(19) United States
(12) Patent Application Publication
(10) Pub. No.: US 2026/0082854 A1
(43) Pub. Date: Mar. 19, 2026

(54) SUBSTRATE PROCESSING APPARATUS, SUBSTRATE PROCESSING METHOD, TRANSPORT DEVICE, TRANSPORT METHOD, PROGRAM, AND STORAGE MEDIUM

(71) Applicant: EBARA CORPORATION, Tokyo (JP)

(72) Inventor: Shuichi KAMATA, Tokyo (JP)

(21) Appl. No.: 19/328,240

(22) Filed: Sep. 15, 2025

(30) Foreign Application Priority Data
Sep. 17, 2024 (JP) 2024-159998

(51) Int. Cl. H01L 21/67; B24B 37/34; H01L 21/304; H01L 21/677; H01L 21/687

(52) U.S. Cl. CPC H10P 72/0606; B24B 37/345; H10P 52/00; H10P 72/3302; H10P 72/76

(57) ABSTRACT

The present invention proposes a substrate processing apparatus, a transport device, and the like capable of properly implementing processing even when a malfunction occurs in a sensor for detecting that an object such as a substrate is properly positioned. The substrate processing apparatus is equipped with a controller configured to accept a predetermined external input if a first sensor does not detect that a substrate is properly positioned in a first holding mechanism when the substrate is transferred from a second holding mechanism to the first holding mechanism and to allow the substrate to be processed or transported using the first holding mechanism based on the predetermined external input being performed regardless of the detection by the first sensor.

### CROSS-REFERENCE TO RELATED APPLICATIONS

This application is based on and claims priority from Japanese Patent Application No. 2024-159998, filed on Sep. 17, 2024, with the Japan Patent Office, the disclosure of which is incorporated herein in its entirety by reference.

### TECHNICAL FIELD

The present invention relates to a substrate processing apparatus, a substrate processing method, a transport device, a transport method, and a storage medium.

### BACKGROUND

A chemical mechanical polishing (CMP) apparatus is used to planarize surfaces of substrates in the manufacture of semiconductor devices. The substrates used in the manufacture of semiconductor devices often have a disk shape. In addition, there is a growing demand for flatness when planarizing not only surfaces of substrates of semiconductor devices but also surfaces of rectangular substrates such as a CCL substrate (Copper Clad Laminate substrate), a PCB (Printed Circuit Board) substrate, a photomask substrate, and a display panel. Furthermore, there is also a growing demand for planarizing surfaces of package substrates on which electronic devices such as PCB substrates are mounted.

Generally, such a substrate processing apparatus is equipped with a top ring for holding a substrate and pressing the substrate against a polishing surface and a transport stage for transferring the substrate to and from the top ring and transporting the substrate. In addition, a substrate processing apparatus equipped with sensors that detect that a substrate has been properly transferred from a top ring to a transport stage is known (for example, refer to Japanese Patent Laid-Open Publication No. 2015-082586). In the apparatus described in Japanese Patent Laid-Open Publication No. 2015-082586, a plurality of sensors for detecting different locations on the substrate determine whether or not the substrate is properly seated on the transport stage. If the substrate is not detected to be properly seated on the transport stage when the substrate is transferred from the top ring to the transport stage, processing of the substrate is stopped. Subsequently, a user confirms a malfunction of the substrate and the processing is restarted after the substrate is discarded, replaced, or arranged once again.

### SUMMARY

In the substrate processing apparatus described above, when a malfunction such as a failure occurs in a sensor for detecting that a substrate has been properly transferred, processing is stopped until the malfunction is resolved by replacing the sensor or the like even though there is no problem with the substrate processing. In the substrate processing apparatus described above, the substrate placed on the transport stage is wetted with a liquid such as pure water for polishing, and if a long time elapses, deterioration such as corrosion of the substrate may occur and may necessitate discarding of the substrate.

In addition, regardless of the substrate processing apparatus, there is a similar issue with a transport device that transports an object from a second mechanism to a first mechanism. Specifically, when the object is transferred from the second mechanism to the first mechanism, if a sensor malfunctions and fails to detect that the object is properly positioned in the first mechanism, processing will be stopped even though there is no problem with the transport of the object.

The present invention has been made in consideration of the problems described above and an object of the present invention is to propose a substrate processing apparatus, a transport device, and the like capable of properly implementing processing even when a malfunction occurs in a sensor for detecting that an object such as a substrate is properly positioned.

An embodiment of the present invention proposes a substrate processing apparatus, including: a first holding mechanism for holding a substrate; a second holding mechanism for holding a substrate, the second holding mechanism being configured to be capable of transferring a substrate to and from the first holding mechanism; a first sensor for detecting that a substrate is properly positioned in the first holding mechanism; and a controller configured to accept a predetermined external input if the first sensor does not detect that a substrate is properly positioned in the first holding mechanism when the substrate is transferred from the second holding mechanism to the first holding mechanism and to allow the substrate to be processed or transported using the first holding mechanism based on the predetermined external input being performed regardless of the detection by the first sensor.

An embodiment of the present invention proposes a substrate processing method in a substrate processing apparatus including: a first holding mechanism for holding a substrate; a second holding mechanism for holding a substrate, the second holding mechanism being configured to be capable of transferring a substrate to and from the first holding mechanism; and a first sensor for detecting that a substrate is properly positioned in the first holding mechanism, the substrate processing method including: detecting whether or not a substrate is properly positioned in the first holding mechanism with the first sensor when the substrate is transferred from the second holding mechanism to the first holding mechanism; accepting a predetermined external input to the substrate processing apparatus when the substrate is not detected to be properly positioned in the first holding mechanism; and allowing the substrate to be processed or transported using the first holding mechanism based on the predetermined external input being performed regardless of the detection by the first sensor.

An embodiment of the present invention proposes a program that causes a computer to execute a substrate processing method in a substrate processing apparatus, the method including: detecting whether or not a substrate is properly positioned in a first holding mechanism with a first sensor when the substrate is transferred from a second holding mechanism to the first holding mechanism; accepting a predetermined external input to the substrate processing apparatus when the substrate is not detected to be properly positioned in the first holding mechanism; and allowing the substrate to be processed or transported using the first holding mechanism based on the predetermined external input being performed regardless of the detection by the first sensor.

An embodiment of the present invention proposes a transport device, including: a first holding mechanism for holding an object; a second holding mechanism for holding an object, the second holding mechanism being configured to be capable of transferring an object to and from the first holding mechanism; a first sensor for detecting that an object is properly positioned in the first holding mechanism; and a controller configured to accept a predetermined external input if the first sensor does not detect that an object is properly positioned in the first holding mechanism when the object is transferred from the second holding mechanism to the first holding mechanism and to allow the object to be processed or transported using the first holding mechanism based on the predetermined external input being performed regardless of the detection by the first sensor.

An embodiment of the present invention proposes a transport method in a transport device including: a first holding mechanism for holding an object; a second holding mechanism for holding an object, the second holding mechanism being configured to be capable of transferring an object to and from the first holding mechanism; and a first sensor for detecting that an object is properly positioned in the first holding mechanism, the transport method including: detecting whether or not an object is properly positioned in the first holding mechanism with the first sensor when the object is transferred from the second holding mechanism to the first holding mechanism; accepting a predetermined external input to the transport device when the object is not detected to be properly positioned in the first holding mechanism; and allowing the object to be processed or transported using the first holding mechanism based on the predetermined external input being performed regardless of the detection by the first sensor.

An embodiment of the present invention proposes a program that causes a computer to execute a transport method in a transport device, the method including: detecting whether or not an object is properly positioned in a first holding mechanism with a first sensor when the object is transferred from a second holding mechanism to the first holding mechanism; accepting a predetermined external input to the transport device when the object is not detected to be properly positioned in the first holding mechanism; and allowing the object to be processed or transported using the first holding mechanism based on the predetermined external input being performed regardless of the detection by the first sensor.

### BRIEF DESCRIPTION OF DRAWINGS

FIG. 1 is a plan view showing an overall configuration of a substrate processing apparatus according to an embodiment of the present invention.

FIG. 2 is a perspective view schematically showing a first polishing device according to the present embodiment.

FIG. 3 is a schematic sectional view of a top ring that constitutes a substrate holding device that holds a wafer being an object to be polished and presses the wafer against a polishing surface on a polishing table.

FIG. 4 is a perspective view showing a transport robot according to the present embodiment.

FIG. 5 is a plan view schematically showing an example of a first linear transporter.

FIG. 6 is a flowchart showing an example of substrate transfer processing according to the present embodiment that is executed by a controller.

FIG. 7 is a flowchart showing an example of substrate transfer processing according to a second embodiment that is executed by a controller.

FIG. 8 is a flowchart showing an example of substrate transfer processing according to a third embodiment that is executed by a controller.

FIG. 9 is a diagram schematically showing an example of a transfer of a wafer between a transport robot and a transport unit.

FIG. 10 is a schematic view showing a schematic configuration of a transport device according to a fourth embodiment.

FIG. 11 is a flowchart showing an example of object transfer processing according to a fourth embodiment that is executed by a controller.

### DETAILED DESCRIPTION

Hereinafter, embodiments of a substrate processing apparatus, a substrate processing method, a transport device, a transport method, a program, and a storage medium according to the present invention will be described together with accompanying drawings. In the accompanying drawings, same or similar elements are assigned same or similar reference signs, and redundant descriptions of same or similar elements in the description of each embodiment may be omitted. In addition, the features demonstrated in each embodiment are also applicable to other embodiments as long as no mutual inconsistencies arise.

### First Embodiment

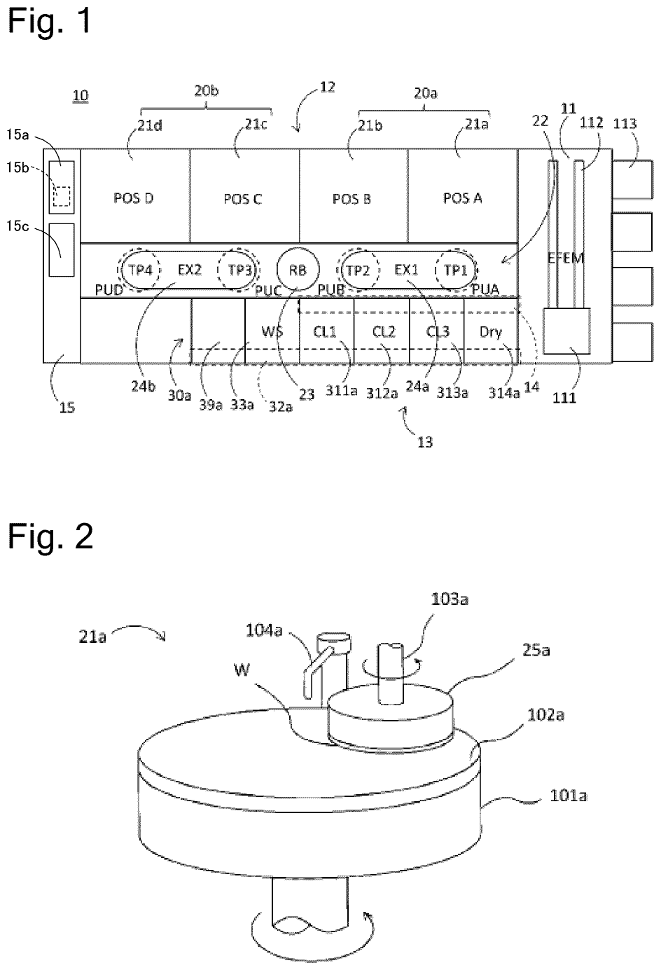

FIG. 1 is a plan view showing an overall configuration of a substrate processing apparatus according to an embodiment of the present invention. As shown in FIG. 1, a substrate processing apparatus 10 according to the present embodiment is equipped with a housing with an approximately rectangular shape in a plan view and an interior of the housing is divided by partition walls into a load port 11, a polishing module 12, and a cleaning module 13. The load port 11, the polishing module 12, and the cleaning module 13 are assembled independently and vented independently. In addition, the substrate processing apparatus has a controller 15 that controls substrate processing operations.

The load port 11 is equipped with a plurality of (in the present embodiment, four) front-loaders 113 on which a wafer cassette that stocks a large number of wafers (an example of a substrate) W is placed. The front-loaders 113 are arrayed adjacent to each other in a width direction (a direction perpendicular to a longitudinal direction) of the substrate processing apparatus 10. An open cassette, a Standard Manufacturing Interface (SMIF) pod, or a Front Opening Unified Pod (FOUP) can be mounted on the front-loaders 113. While the present embodiment will be described using a circular semiconductor wafer as an example of a substrate, the substrate is not limited to this example and, for example, a square substrate may be used.

In addition, the load port 11 is provided with a travel mechanism 112 that extends in an array direction of the front-loaders 113. A transport robot 111 that is movable in the array direction of the front-loaders 113 is installed on the travel mechanism 112. The transport robot 111 is configured to be capable of accessing the wafer cassette mounted on the front-loaders 113 by moving on the travel mechanism 112. In the present embodiment, the transport robot 111 is equipped with two hands: an upper hand and a lower hand. As an example, the transport robot 111 uses the upper hand to return a processed wafer W to the wafer cassette and uses the lower hand to transport a wafer W prior to polishing. However, the transport robot 111 is not limited to such an example and may be configured to transport the wafer W with only one hand. In addition, in the present embodiment, a transport module 14 for transporting the wafer prior to polishing from the load port 11 to the polishing module 12 is provided. The transport module 14 is provided so as to extend in the longitudinal direction of the substrate processing apparatus 10. As the transport module 14, for example, a motor drive mechanism using a ball screw or an air cylinder is used.

The polishing module 12 is a region where polishing of the wafer W is performed and has a first polishing module 20a, a second polishing module 20b, and a polisher transport mechanism 22. The first polishing module 20a has a first polishing device 21a and a second polishing device 21b and the second polishing module 20b has a third polishing device 21c and a fourth polishing device 21d. The polisher transport mechanism 22 is arranged so as to be adjacent to the transport module 14, the first polishing module 20a, and the second polishing module 20b, respectively. The polisher transport mechanism 22 is arranged between the cleaning module 13, and the first polishing module 20a and the second polishing module 20b, in the width direction of the substrate processing apparatus 10. The first to fourth polishing devices 21a to 21d are arrayed in the longitudinal direction of the substrate processing apparatus 10. Alternatively, one, two, three, or five or more polishing devices may be provided.

A top ring 25a of the first polishing device 21a moves between a polishing position and a first substrate transport position TP1 due to a swing operation of a top ring head. Transfer of a wafer to the first polishing device 21a is performed at the first substrate transport position TP1. In a similar manner, top rings of the second to fourth polishing devices 21b to 21d move between a polishing position and second to fourth substrate transport positions TP2 to TP4 due to a swing operation of a top ring head, respectively, and transfer of a wafer to the second to fourth polishing devices 21b to 21d is performed at the second to fourth substrate transport positions TP2 to TP4.

The polisher transport mechanism 22 has a first linear transporter 24a that transports the wafer W to the first polishing module 20a and a second linear transporter 24b that transports the wafer W to the second polishing module 20b. In addition, the polisher transport mechanism 22 has a transport robot 23 arranged between the first linear transporter 24a and the second linear transporter 24b. In the illustrated example, the transport robot 23 is arranged at approximately center of the housing of the substrate processing apparatus 10. The transport robot 23 performs transfer of wafers among the first linear transporter 24a, the second linear transporter 24b, the transport module 14, and the cleaning module 13. Note that a swing transporter for transporting the wafer W may be provided in place of or in addition to the transport robot 23.

FIG. 2 is a perspective view schematically showing the first polishing device 21a. Since the second to fourth polishing devices 21b to 21d have similar configurations to the first polishing device 21a, hereinafter, the first polishing device 21a will be described. The first polishing device 21a is equipped with a polishing table 101a to which a polishing pad 102a is affixed and the top ring 25a which holds the wafer W and presses the wafer W against the polishing pad 102a on the polishing table 101a. The top ring 25a and the polishing table 101a are configured to be rotatable around axial centers thereof as indicated by arrows in FIG. 2. In addition, a polishing liquid supply nozzle 104a for supplying a polishing liquid (also referred to as a slurry) and a dressing liquid (for example, pure water) to the polishing pad 102a, a dresser (not illustrated) for dressing a polishing surface of the polishing pad 102a, and an atomizer (not illustrated) that atomizes and sprays a mixed gas of a liquid (for example, pure water) and a gas (for example, nitrogen gas) or a liquid (for example, pure water) on the polishing surface are provided above the polishing table 101a. During polishing, the polishing liquid is supplied from the polishing liquid supply nozzle 104a to the polishing surface of the polishing pad 102a and the wafer W being an object to be polished is pressed against the polishing surface by the top ring 25a and is polished.

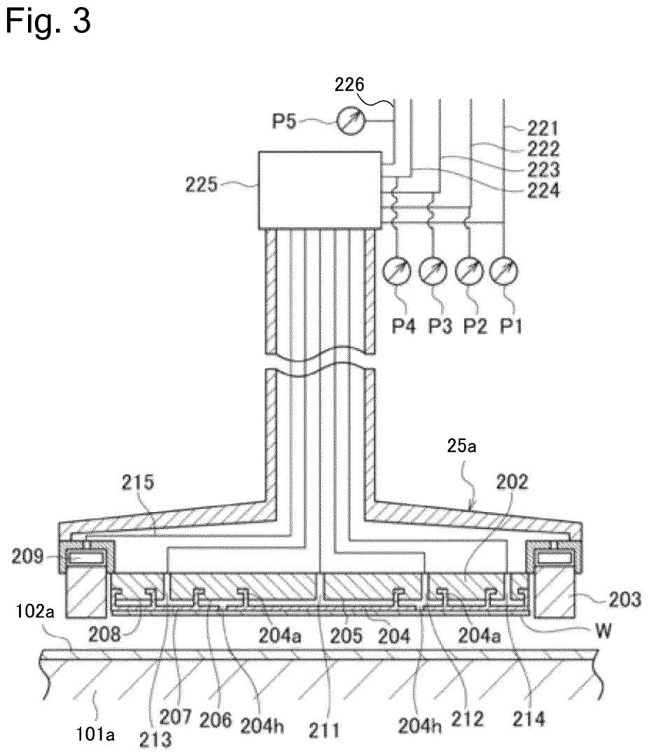

Next, the top ring (substrate holding device) 25a will be described in greater detail. FIG. 3 is a schematic sectional view of the top ring 25a that constitutes a substrate holding device that holds the wafer W being an object to be polished and presses the wafer W against a polishing surface on a polishing table. In FIG. 3, only main components that constitute the top ring 25a are illustrated.

As shown in FIG. 3, the top ring 25a is equipped with a top ring main body 202 that presses the wafer W against the polishing pad 102a and a retainer ring 203 that directly presses the polishing pad 102a. The top ring main body 202 is constituted of an approximately disk-shaped member, and the retainer ring 203 is attached to an outer circumferential part of the top ring main body 202. The top ring main body 202 is formed of a resin such as engineering plastic (for example, PEEK). A membrane (elastic film) 204 that comes into contact with a rear surface of the wafer is attached to a lower surface of the top ring main body 202. The membrane 204 demarcates a pressure chamber and a lower surface of the membrane 204 demarcates a substrate holding surface that comes into contact with the wafer W. The membrane 204 is formed from rubber materials with excellent strength and durability such as ethylene propylene rubber (EPDM), polyurethane rubber, and silicone rubber.

As one example, in the example shown in FIG. 3, the membrane 204 has a plurality of concentric partition walls 204a, and a circular center chamber 205, an annular ripple chamber 206, an annular outer chamber 207, and an annular edge chamber 208 are formed between an upper surface of the membrane 204 and the lower surface of the top ring main body 202 by the partition walls 204a. In other words, the center chamber 205 is formed in a central part of the top ring main body 202, and the ripple chamber 206, the outer chamber 207, and the edge chamber 208 are concentrically formed in sequence from the center in an outer circumferential direction. The membrane 204 has a plurality of holes 204h that penetrate in a thickness direction of an elastic film for wafer suction in a ripple area (ripple chamber 206). While the holes 204h are provided in the ripple area in the example shown in FIG. 3, the holes 204h may be provided outside of the ripple area. In addition, while the membrane 204 has the plurality of concentric partition walls 204a in the example shown in FIG. 3, the membrane 204 is not limited to such an example and partition walls may be provided so as to divide a plurality of regions in a circumferential direction or the partition walls 204a need not be provided.

A flow path 211 in communication with the center chamber 205, a flow path 212 in communication with the ripple chamber 206, a flow path 213 in communication with the outer chamber 207, and a flow path 214 in communication with the edge chamber 208 are formed inside the top ring main body 202, respectively. In addition, each of the flow paths 211 to 214 is connected via a rotary joint 225 to flow paths 221 to 224 connected to a vacuum source and a pressure adjuster (both not illustrated). The flow paths 221 to 224 are provided with pressure sensors P1 to P4 and detected signals of the pressure sensors P1 to P4 are input to the controller 15.

In addition, a retainer ring compression chamber 209 made of an elastic film is also formed directly above the retainer ring 203, and the retainer ring compression chamber 209 is connected to a flow path 226 via a flow path 215 formed inside the top ring main body (carrier) 202 and the rotary joint 225. Furthermore, the flow path 226 is connected to a vacuum source and a pressure adjuster (both not illustrated). The flow path 226 is provided with a pressure sensor P5 and detected signals of the pressure sensor P5 are input to the controller 15.

In the top ring 25a configured as described above, the vacuum source and the pressure adjuster enable pressure inside the center chamber 205, the ripple chamber 206, the outer chamber 207, the edge chamber 208, and the retainer ring compression chamber 209 to be independently adjusted, respectively. Such a structure enables a pressing force that presses the wafer W against the polishing pad 102a to be adjusted for each region of the wafer W and enables a pressing force by which the retainer ring 203 presses the polishing pad 102a to be adjusted.

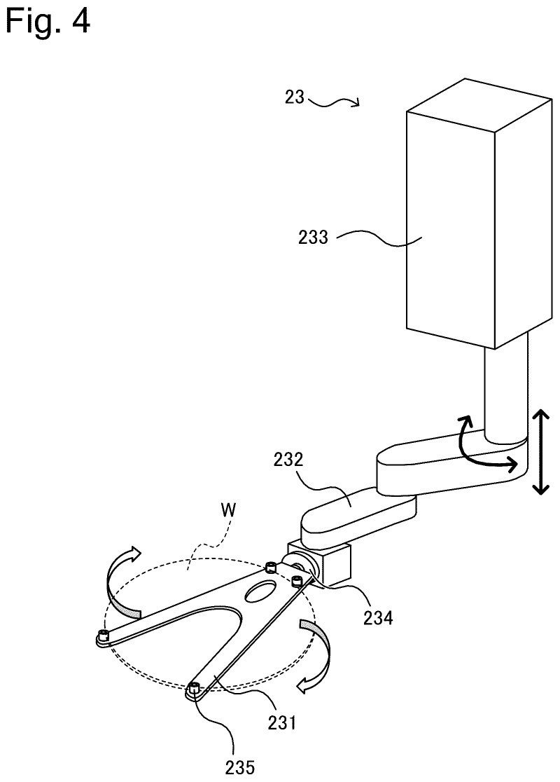

FIG. 4 is a perspective view showing the transport robot 23. As shown in FIG. 4, the transport robot 23 has a hand 231 for holding the wafer W, a reversal mechanism 234 for turning the hand 231 upside down, an extensible arm 232 for supporting the wafer W, and a robot main body 233 including an arm vertical movement mechanism for moving the arm 232 up and down and an arm rotation mechanism for rotating the arm 232 around a vertical axis. The robot main body 233 is attached so as to be suspended from a frame of a ceiling of the polishing module 12. In addition, the transport robot 23 is provided with a sensor 235 for detecting that the wafer W is properly positioned in the hand 231. The sensor 235 may be constituted of a single sensor or a plurality of sensors. As an example, a sensor that detects a load applied to a grasping mechanism for grasping the wafer W can be used as the sensor 235. In addition, various sensors such as distance sensors (laser sensor, infrared sensor, X-ray sensor, and the like), image sensors, ultrasonic sensors, and contact sensors (such as a mechanical sensor) can be used as the sensor 235.

In the present embodiment, the hand 231 is capable of accessing the transport module 14. In addition, the hand 231 is also capable of accessing the first linear transporter 24a and the second linear transporter 24b of the polishing module 12. Therefore, the wafers W consecutively transported from the transport module 14 to the polishing module 12 are sorted to the first linear transporter 24a and the second linear transporter 24b by the transport robot 23. Since the first linear transporter 24a and the second linear transporter 24b have similar configurations, hereinafter, the first linear transporter 24a will be described.

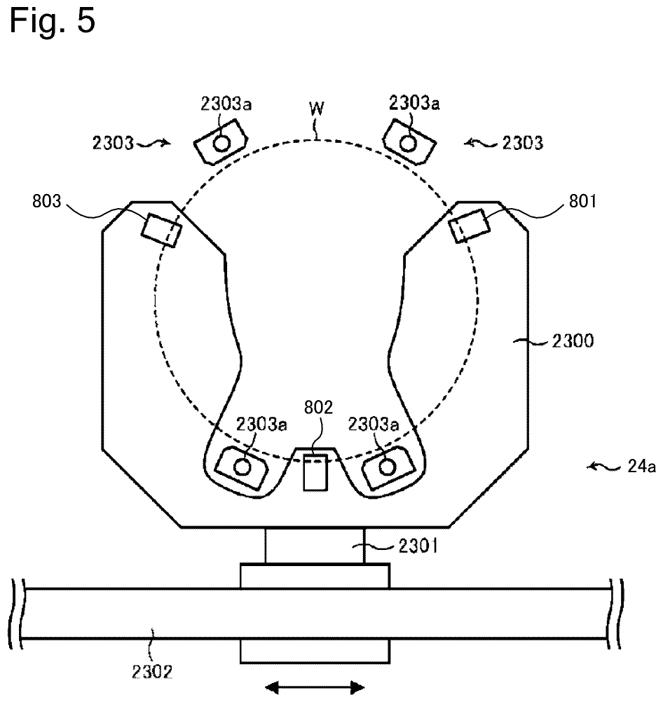

FIG. 5 is a plan view schematically showing an example of the first linear transporter 24a. The first linear transporter 24a is equipped with a transport hand 2300 for holding the wafer W, a vertical movement mechanism 2301 for moving the transport hand 2300 in the vertical direction, a horizontal movement mechanism 2302 for moving the transport hand 2300 and the vertical movement mechanism 2301 in an alignment direction of the first to fourth polishing devices 21a to 21d, and retainer ring stations 2303 provided at each of the positions (first to fourth substrate transport positions TP1 to TP4) where the wafer W is transferred to and from the top ring 25a, respectively. The first and second linear transporters 24a and 24b are configured so as to be equipped with a plurality of sets, each set including the transport hand 2300, the vertical movement mechanism 2301, and the horizontal movement mechanism 2302.

The transport hand 2300 has a shape that supports a part of an outer circumferential side of the lower surface of the wafer W. The retainer ring station 2303 is equipped with a plurality of push-up pins 2303a which are arranged at positions opposing the retainer ring 203 of the top ring 25a and which push up the retainer ring 203. The retainer ring station 2303 is installed at a position where the retainer ring station 2303 does not interfere with the transport hand 2300 when the transport hand 2300 is elevated by the vertical movement mechanism 2301 in a state where the transport hand 2300 is positioned below the retainer ring station 2303 by the horizontal movement mechanism 2302. Note that the retainer ring station 2303 may be equipped with a release nozzle that supplies a fluid for releasing the wafer W.

While specific components of the vertical movement mechanism 2301 and the horizontal movement mechanism 2302 are omitted in FIG. 5, for example, the vertical movement mechanism 2301 and the horizontal movement mechanism 2302 are constructed by combining an actuator such as a motor or an air cylinder, a drive force transmission mechanism such as a linear guide, a ball screw, a gear, a coupling, a belt, or a bearing, and a sensor such as a linear sensor, an encoder sensor, or a limit sensor, as appropriate. In addition, instead of providing the first and second linear transporters 24a and 24b with the vertical movement mechanism 2301, the substrate processing apparatus 10 may be equipped with a pusher or the like for transferring the wafer W between the linear transporters 24a and 24b and the top ring 25a.

In addition, the transport hand 2300 according to the present embodiment is provided with three sensors 811 to 813 for detecting that the wafer W has been transferred. The sensors 811 to 813 are provided in order to detect whether or not the wafer W is properly positioned in the first and second linear transporters 24a and 24b. The sensors 811 to 813 are arranged separated in a circumferential direction of the wafer W so as to detect a different region of the wafer W, respectively. Detected signals of the sensors 811 to 813 are input to the controller 15. Note that the transport hand 2300 may be provided with one, two, or four or more sensors for detecting that the wafer W has been transferred. As the sensors 811 to 813, an optical sensor can be used which is equipped with a light projector and a light receiver and which detects the wafer W based on whether or not light from the light projector can be received by the light receiver. In addition, when the wafer W is arranged between the light projector and the light receiver, detection that the wafer W is properly positioned may be performed when light from the light projector is blocked by the wafer W and the light is no longer detected by the light receiver. However, the sensors 811 to 813 are not limited to such an example and various sensors such as distance sensors (laser sensor, infrared sensor, X-ray sensor, and the like), image sensors, ultrasonic sensors, and contact sensors (such as a mechanical sensor) can be adopted as the sensors 811 to 813.

Let us now refer again to FIG. 1. The cleaning module 13 is a region where a polished wafer is cleaned and is equipped with a wafer station 33a as a temporary table for temporarily placing substrates, four cleaning modules 311a to 314a (hereinafter, also referred to as primary to quaternary cleaning modules) for cleaning substrates after polishing, and a stage 32a for holding and transporting wafers between the wafer station 33a and the cleaning modules 311a to 314a. The wafer station 33a and the plurality of cleaning modules 311a to 314a are arranged in series in the longitudinal direction of the substrate processing apparatus 10.

As cleaning machines of the primary cleaning module 311a and the secondary cleaning module 312a, for example, a roll-type cleaning machine that rotates roll-shaped sponges arranged vertically, presses the sponges against the front surface and the rear surface of a wafer, and cleans the front surface and the rear surface of the wafer can be used. In addition, as a cleaning machine of the tertiary cleaning module 313a, for example, a pencil-type cleaning machine that presses a hemispherical sponge against a wafer while rotating the sponge to clean the wafer can be used. As a cleaning machine of the quaternary cleaning module 314a, for example, a pencil-type cleaning machine which is capable of cleaning the rear surface of a wafer by rinsing the wafer and pressing a hemispherical sponge against the front surface of the wafer while rotating the sponge to clean the front surface of the wafer can be used. The cleaning machine of the quaternary cleaning module 314a is equipped with a stage that rotates a chucked wafer at high speed and has a function (spin dry function) of drying the wafer after cleaning by rotating the wafer at high speed. Note that in each of the cleaning modules 311a to 314a, a megasonic-type cleaning machine that cleans by applying ultrasonic waves to a cleaning solution may be additionally provided in addition to the roll-type cleaning machine or the pencil-type cleaning machine described above.

The controller 15 is provided in order to control each component of the substrate processing apparatus 10. The controller 15 may be configured as a microcomputer equipped with a CPU, a memory 15a, a display apparatus 15c, and the like and capable of performing predetermined functions using software or may be configured as a hardware circuit for performing dedicated arithmetic processing. The memory 15a is an example of a storage medium and stores a program 15b for realizing the method according to one embodiment of the present invention. The display apparatus 15c is an apparatus for displaying information to a user and, as an example, the display apparatus 15c is constituted of a display device arranged outside of the substrate processing apparatus 10. In addition, the display apparatus 15c according to the present embodiment has a function of an input apparatus that enables external input by the user. However, the substrate processing apparatus 10 may be equipped with the display apparatus 15c and an input apparatus, respectively.

Normal operations performed by the substrate processing apparatus 10 configured as described above will be described. In the substrate processing apparatus 10, first, the wafer W prior to polishing is retrieved from a wafer cassette of the front-loader 113 by the transport robot 111 of the load port 11 and transferred to the transport module 14. Next, the wafer W is transferred from the transport module 14 to the transport robot 23 and turned upside down together with the hand 231 by the reversal mechanism 234 of the transport robot 23. Accordingly, a processing surface of the wafer W is oriented to face downward. Next, the wafer W is transferred from the transport robot 23 to the first linear transporter 24a or the second linear transporter 24b and carried into the first to fourth polishing devices 21a to 21d from the first linear transporter 24a or the second linear transporter 24b. In the first to fourth polishing devices 21a to 21d, the wafer W is sucked and held by the top ring 25a and is polished by coming into contact with the polishing pad 102a.

After polishing of the wafer W is finished, the polished wafer W is transferred from the first to fourth polishing devices 21a to 21d to the transport robot 23 through the first linear transporter 24a or the second linear transporter 24b. Next, the wafer W is turned upside down together with the hand 231 by the reversal mechanism 234 of the transport robot 23. Accordingly, the processing surface of the wafer W is oriented to face upward. The wafer W is transferred from the transport robot 23 to the cleaning module 13 and cleaning and drying are performed in the cleaning module 13. After the cleaning and drying processing in the cleaning module 13 is finished, the wafer W is retrieved from the cleaning module 13 to the load port 11 to end the substrate processing in the substrate processing apparatus 10.

Note that the substrate processing or the processing with respect to the wafer W means processing performed with respect to the wafer W in the substrate processing apparatus 10 and may include transporting the wafer W. In other words, while the expression “processing or transport” may be used in the present specification to facilitate understanding, “processing” may or may not include transport.

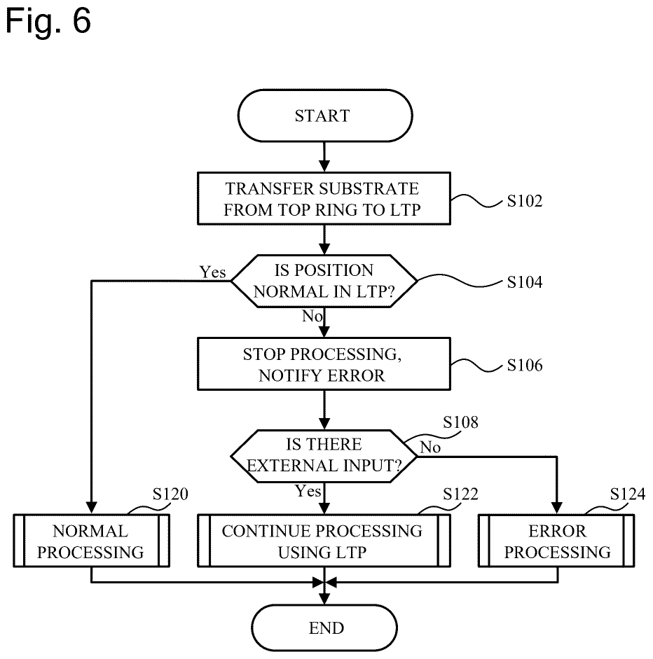

Next, an operation when transferring the wafer W from the top ring 25a to the first and second linear transporters 24a and 24b (hereinafter, the first linear transporter 24a as a representative) in the substrate processing apparatus 10 according to the present embodiment will be described. FIG. 6 is a flowchart showing an example of substrate transfer processing according to the present embodiment that is executed by a controller. The processing shown in FIG. 6 is started when the polishing processing of the wafer W ends in the first to fourth polishing devices 21a to 21d (hereinafter, the first polishing device 21a as a representative). Note that in the example shown in FIG. 6, the sensors 811 to 813 of the linear transporter 24a correspond to an example of the “first sensor”.

Once polishing processing of the wafer W ends, the top ring 25a that holds the wafer W moves to above the first substrate transport position TP1. Next, due to the top ring 25a releasing the wafer W, the wafer W is transferred from the top ring 25a to the transport hand 2300 of the first linear transporter 24a (step S102). At this point, the sensors 811 to 813 of the first linear transporter 24a detect whether or not the wafer W has been properly transferred to the transport hand 2300 (step S104). In the present embodiment, when the wafer W is detected by all three sensors 811 to 813, the controller 15 determines that the wafer W is properly positioned in the first linear transporter 24a and has been properly transferred. On the other hand, when the wafer W is not detected by at least one of the three sensors 811 to 813, the controller 15 determines that the wafer W is not properly positioned in the first linear transporter 24a and has not been properly transferred.

When the sensors 811 to 813 detect that the wafer W is properly positioned in the first linear transporter 24a (S104: Yes), the controller 15 subsequently performs normal processing with respect to the wafer W (step S120). Normal processing is processing along normal operations performed by the substrate processing apparatus 10 described above. As an example, the wafer W is transferred from the first linear transporter 24a to the wafer station 33a of the cleaning module 13 via the transport robot 23. After the cleaning and drying processing is finished, the wafer W is retrieved to the load port 11 via the stage 32a of the cleaning module 13. Then, due to the storage of the wafer W in the front-loader 113, the substrate processing in the substrate processing apparatus 10 is finished.

On the other hand, when the sensors 811 to 813 do not detect that the wafer W is properly positioned in the first linear transporter 24a (S104: No), the controller 15 determines that there is a possibility that the wafer W has not been properly transferred. At this point, the controller 15 stops the processing with respect to the wafer W in question and notifies an error (step S106), and asks for a predetermined external input (step S108). In this case, as the notification of an error, for example, the display apparatus 15c, a lamp (not illustrated), a buzzer, or the like may be used to notify the fact that the wafer W is not being properly detected by the sensors 811 to 813. In addition, the predetermined external input is an input used by the user to allow processing to be continued regardless of the detection by the sensors 811 to 813 when the wafer W is not properly detected by the sensors 811 to 813. Specifically, the controller 15 displays a message on the display apparatus 15c asking whether or not to continue transport. As an example, the user may visually inspect an interior of the substrate processing apparatus 10 or, in other words, the first linear transporter 24a and the wafer W, to confirm that the wafer W is properly positioned and subsequently perform the predetermined external input. As another example, the user may view an image photographed by a camera (not illustrated) provided inside the substrate processing apparatus 10 and displayed on the display apparatus 15c to confirm that the wafer W is properly positioned and subsequently perform the predetermined external input. Accordingly, when it is determined that the wafer W is properly positioned and that there is a malfunction in the sensors 811 to 813, the user can allow processing to be continued by the external input. Accordingly, the user can confirm that the wafer W is properly positioned and determine that there is a malfunction in the sensors 811 to 813. Therefore, the user performs an (external) input to allow continued transport by operating the display apparatus 15c. Such a predetermined external input may be performed by having the user operate an inputter (not illustrated) provided in the substrate processing apparatus 10 or performed from the outside through wired or wireless communication. In addition, as an example, the predetermined external input may be enabled to be performed in conjunction with the notification of an error. Furthermore, the controller 15 may notify the user by using the display apparatus 15c or the like to perform the predetermined external input together with the notification of an error and ask the user for the predetermined external input.

When the predetermined external input is performed by the user (S108: Yes), the controller 15 continues processing of the wafer W using the first linear transporter 24a regardless of the detection by the sensors 811 to 813 (step S122). In this case, holding and transport of the wafer W by the first linear transporter 24a are allowed regardless of the detection by the sensors 811 to 813. In this case, as an example, processing may be performed in the same manner as the normal processing described in step S120 above. Alternatively, as another example, the controller 15 may execute predetermined sensor malfunction processing for malfunctions of the sensors 811 to 813 which differs from the normal processing. As an example, in the sensor malfunction processing, time until the wafer W is stored in the front-loader 113 may be shortened as compared to normal processing. As a specific example, processing in the cleaning module 13 may be partially simplified or partially omitted so that processing is finished in a shorter period of time within a range where the quality of the wafer W does not deteriorate. Accordingly, at least a part of the substrate processing apparatus 10 can be stopped until maintenance processing such as replacement of the sensors 811 to 813 is performed while preventing the quality of the wafer W being processed from deteriorating.

On the other hand, when the user does not perform the predetermined external input (S108: No), the controller 15 determines that a transfer error has occurred when the wafer W is transferred from the top ring 25a to the first linear transporter 24a and executes predetermined transport error processing (S124). In this case, “when the user does not perform the predetermined external input” can include when the user does not perform the predetermined external input within a predetermined period of time (for example, a few minutes) and when the user performs an external input indicating that processing of the wafer W is not allowed. In the transport error processing, the controller 15 may prohibit holding and transport of the wafer W by the first linear transporter 24a. In addition, in the transport error processing, the controller 15 may notify that a transfer error of the wafer W has occurred using the display apparatus 15c, a lamp (not illustrated), a buzzer, or the like.

According to the substrate transfer processing described above, control by the controller 15 when the wafer W is transferred from the top ring 25a (an example of the second holding mechanism) to the first linear transporter 24a (an example of the first holding mechanism) is disclosed. In other words, when the sensors 811 to 813 do not detect that the wafer W is properly positioned, the controller 15 accepts a predetermined external input from the user. Based on the predetermined external input being performed, the controller 15 allows processing of the wafer W using the first linear transporter 24a regardless of the detection by the sensors 811 to 813. Such control enables even cases where a malfunction has occurred in the sensors 811 to 813 to be suitably accommodated.

### Second Embodiment

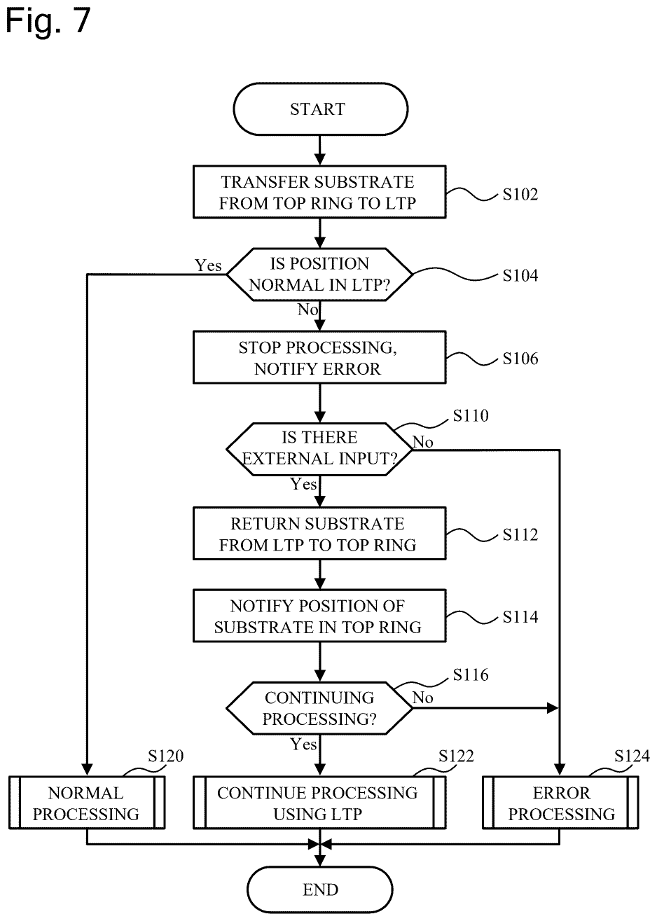

Next, a transfer operation of the wafer W by the substrate processing apparatus 10 according to a second embodiment will be described. The substrate processing apparatus 10 according to the second embodiment has the same apparatus configuration as the substrate processing apparatus 10 according to the first embodiment. FIG. 7 is a flowchart showing an example of substrate transfer processing according to the second embodiment that is executed by the controller 15. The processing shown in FIG. 7 is the same as the processing in FIG. 6 with the exception of processing of steps S110 to S116 being executed in place of step S108 in FIG. 6, and redundant descriptions will be omitted. Note that in the example shown in FIG. 7, the sensors 811 to 813 of the linear transporter 24a correspond to an example of the “first sensor” and the pressure sensors P1 to P4 of the top ring 25a correspond to an example of the “second sensor”.

When the sensors 811 to 813 do not detect that the wafer W is properly positioned in the first linear transporter 24a (S104: No), the controller 15 stops processing with respect to the wafer W in question and notifies an error (step S106), and asks for an external input of a return operation (step S110). Here, the external input of a return operation corresponds to an example of the “predetermined external input”. Note that the user may perform the external input of a return operation by confirming the interior of the substrate processing apparatus 10 by visual inspection or a photographed image. Alternatively, the user may perform the external input of a return operation when the interior of the substrate processing apparatus 10 cannot be confirmed by visual inspection or a photographed image. When the external input of a return operation is not performed (S110: No), the controller 15 executes predetermined transport error processing (step S124). Note that “when the external input of a return operation is not performed” can include when the user does not perform the external input within a predetermined period of time (for example, a few minutes) and when the user performs an external input indicating that a return operation of the wafer W is not allowed.

When the external input of a return operation is performed (S110: Yes), the controller 15 causes the wafer W to be returned from the first linear transporter 24a to the top ring 25a (step S112). Specifically, negative pressure is generated in lines (flow paths 211 to 214) that lead to a predetermined membrane area so that the wafer W is sucked and held by the membrane 204 of the top ring 25a. Subsequently, the user is notified of whether or not the returned wafer W is properly positioned in the top ring 25a (step S114), and the user is asked for an external input of continuing processing (step S116). In the present embodiment, whether or not the returned wafer W is properly positioned is determined based on whether or not detected values of the pressure sensors P1 to P4 are within a proper region determined in advance. As an example, when the detected values of the pressure sensors P1 to P4 indicate sufficiently low pressure, conceivably, the wafer W is properly held by the top ring 25a and sufficient negative pressure is formed. At the same time, it can be determined that the wafer W being properly held by the top ring 25a is because the wafer W was properly positioned in the linear transporter 24a to begin with and the wafer W was properly returned from the linear transporter 24a. However, the determination of whether or not the returned wafer W is properly positioned is not limited to such examples, and the top ring 25a may be provided with other various sensors such as an optical sensor for detecting the wafer W, and whether or not the returned wafer W is properly positioned may be determined based on detected signals from the other sensors in place of or in addition to the pressure sensors P1 to P4. In addition, in the processing of step S114, as an example, the notification to the user may be performed by the display apparatus 15c. In the processing of step S114, the detected values of the pressure sensors P1 to P4 may be notified or a determination result by the controller 15 regarding whether or not the wafer W is properly positioned may be notified. Furthermore, the external input of continuing processing corresponds to an example of the “predetermined external input”. The user can perform the external input of continuing processing by confirming that the returned wafer W is properly positioned in the processing of step S114. As described above, this is based on the conception that the wafer W being properly returned from the first linear transporter 24a to the top ring 25a is because the wafer W was properly positioned in the linear transporter 24a to begin with and the transfer of the wafer W between the top ring 25a and the first linear transporter 24a was normal. In other words, in the second embodiment, whether the transfer of the wafer W between the top ring 25a and the first linear transporter 24a is normal is confirmed by a return operation of the wafer W in place of or in addition to confirming the interior of the substrate processing apparatus 10 by a visual inspection or a photographed image.

In addition, when the external input of continuing processing is performed by the user (S116: Yes), the controller 15 continues processing using the first linear transporter 24a (step S122). In this case, the wafer W is transferred from the top ring 25a to the first linear transporter 24a once again, and holding and transport of the wafer W by the first linear transporter 24a are allowed regardless of the detection by the sensors 811 to 813. On the other hand, when the external input of continuing processing is not performed (S116: No), the controller 15 executes predetermined transport error processing (step S124). Note that “when the external input of continuing processing is not performed” can include when the user does not perform the external input within a predetermined period of time (for example, a few minutes) and when the user performs an external input indicating that continuing processing of the wafer W is not allowed.

According to the substrate transfer processing of the second embodiment described above, when the sensors 811 to 813 do not detect that the wafer W is properly positioned, the controller 15 accepts an external input of a return operation. The controller 15 causes the wafer W to be returned from the first linear transporter 24a to the top ring 25a based on the external input of a return operation being performed. The controller 15 notifies whether or not the returned wafer W is properly positioned in the top ring 25a and accepts an external input of continuing processing. In addition, based on the external input of continuing processing being performed, the controller 15 allows holding and transport of the wafer W using the first linear transporter 24a regardless of the detection by the sensors 811 to 813. Such control enables even cases where a malfunction has occurred in the sensors 811 to 813 to be suitably accommodated.

### First Modification

In the second embodiment described above, the controller 15 accepts an external input of a return operation and an external input of continuing processing as predetermined external inputs. However, the controller 15 may accept only one of an external input of a return operation and an external input of continuing processing as a predetermined external input. As an example, when the sensors 811 to 813 do not detect that the wafer W is properly positioned, the controller 15 may automatically perform a return operation to the top ring 25a without asking for an external input of a return operation. In this case, processing of the wafer W using the first linear transporter 24a is to be allowed based on the external input of continuing processing after the return operation regardless of the detection by the sensors 811 to 813. In addition, as an example, when it is determined that the returned wafer W is properly positioned in the top ring 25a, the controller 15 may automatically continue processing of the wafer W using the first linear transporter 24a regardless of the detection by the sensors 811 to 813 without asking for an external input of continuing processing. In this case, processing of the wafer W using the first linear transporter 24a is to be allowed based on the external input of a return operation and the determination that the returned wafer W is properly positioned in the top ring 25a. Furthermore, the controller 15 may perform a return operation without asking for a predetermined external input and allow processing of the wafer W to be continued regardless of the detection by the sensors 811 to 813 based on the determination that the returned wafer W is properly positioned in the top ring 25a. Accordingly, when a malfunction has occurred in the sensors 811 to 813, subsequent processing can be automatically performed.

### Second Modification

In the processing of FIG. 7 described above, the controller 15 notifies whether or not the wafer W returned to the top ring 25a is properly positioned (S114), and asks for an external input of continuing processing. However, the controller 15 may ask for an external input of continuing processing when it is determined that the wafer W returned to the top ring 25a is properly positioned and may perform predetermined transport error processing (S124) without asking for the external input of continuing processing when the wafer W returned to the top ring 25a is not properly positioned.

### Third Modification

In the first and second embodiments described above, the controller 15 allows processing of the wafer W to continue based on a predetermined external input when the wafer W is not detected by at least one of the three sensors 811 to 813. However, the controller 15 may allow processing of the wafer W to continue based on a predetermined external input when the wafer W is not detected by only one of the three sensors 811 to 813 but not allow processing of the wafer W to continue when two or more sensors do not detect the wafer W. This is based on the conception that, when two or more sensors do not detect the wafer W, a transfer error of the wafer W has occurred but a malfunction of the sensors 811 to 813 has not. As an example, when two or more sensors do not detect the wafer W in the processing of step S104, the controller 15 may determine that the wafer W has not been properly transferred from the top ring 25a to the linear transporter 24a and may execute transport error processing (step S124).

### Fourth Modification

In the second embodiment described above, when the returned wafer W is properly positioned in the top ring 25a, holding and transport of the wafer W by the first linear transporter 24a are allowed regardless of the detection by the sensors 811 to 813. However, the controller 15 may change control based on detection by the sensors 811 to 813 when the wafer W is once again transferred from the top ring 25a to the first linear transporter 24a. As a specific example, when the wafer W is transferred once again from the top ring 25a to the first linear transporter 24a, if a similar detection is performed by the sensors 811 to 813 such as the same sensor as the first transfer of the wafer W (steps S102 and S104) not detecting the wafer W, the controller 15 may determine that a malfunction has occurred in the sensor and execute the processing of step S122. In addition, as an example, when the wafer W is transferred once again from the top ring 25a to the first linear transporter 24a, if a sensor that differs from the first transfer of the wafer W does not detect the wafer W, the controller 15 may determine that an error has occurred in the transfer of the wafer W and execute the transport error processing of step S124. Furthermore, as an example, when the wafer W is transferred once again from the top ring 25a to the first linear transporter 24a, if the wafer W is properly detected in the first linear transporter 24a, the controller 15 may determine that a temporary malfunction of a sensor has occurred and may execute the normal processing of step S120.

### Fifth Modification

In the first and second embodiments described above, when the controller 15 allows holding and transport of the wafer W by the first linear transporter 24a regardless of the detection by the sensors 811 to 813, the controller 15 may disable detection by the sensors 811 to 813 even when processing other wafers W. Accordingly, when a malfunction has occurred in the sensors 811 to 813, subsequent processing can be performed efficiently. Alternatively, in this case, the controller 15 may disable detection by the sensors 811 to 813 until a predetermined timing and enable detection by the sensors 811 to 813 after the predetermined timing. The processing shown in FIG. 6 or FIG. 7 may be executed once again when the detection by the sensors 811 to 813 is enabled. Here, the predetermined timing can be when a predetermined period of time (for example, several minutes or several tens of minutes) has elapsed. Alternatively, the predetermined timing can be when a predetermined number of (for example, several) wafers W have been processed or when a lot of wafers being processed ends. Accordingly, when a malfunction has occurred in the sensors 811 to 813, subsequent processing can be performed efficiently and a malfunction of a sensor can be prevented from being overlooked for a long period of time.

### Sixth Modification

In the first and second embodiments, the sensors 811 to 813 of the linear transporter 24a correspond to an example of the “first sensor” and the pressure sensors P1 to P4 of the top ring 25a correspond to an example of the “second sensor”. However, the first sensor need only be able to detect that the wafer W is properly positioned in the linear transporter 24a and sensors other than the sensors 811 to 813 may be used as the first sensor. In a similar manner, the second sensor need only be able to detect that the wafer W is properly positioned in the top ring 25a and sensors other than the pressure sensors P1 to P4 may be used as the second sensor. In addition, the first sensor and the second sensor are not limited to those provided in the first linear transporter 24a and the top ring 25a, respectively, and may be attached to another module or a frame (not illustrated) of the substrate processing apparatus 10.

### Third Embodiment

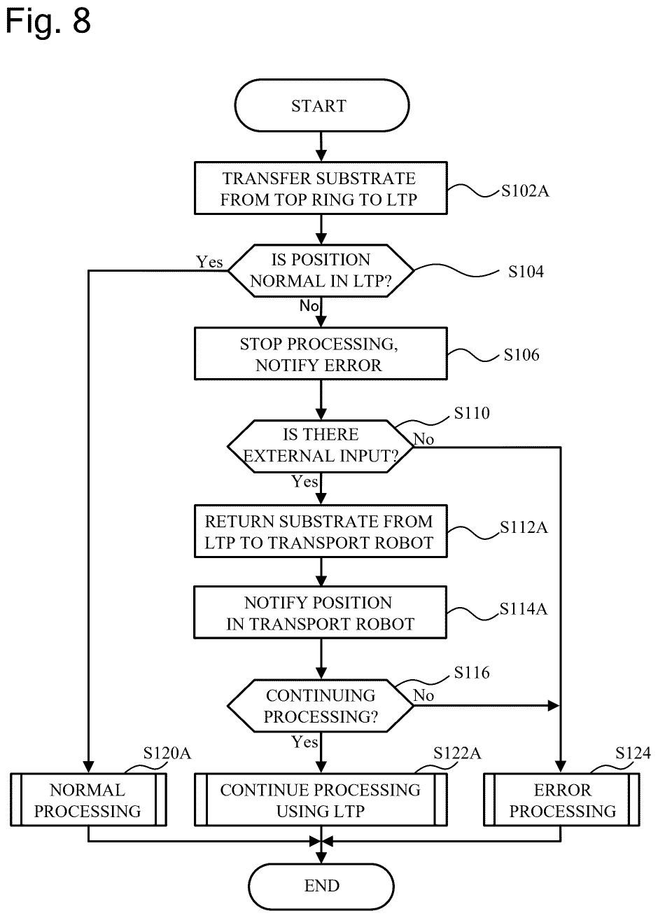

Next, a transfer operation of the wafer W by the substrate processing apparatus 10 according to a third embodiment will be described. The substrate processing apparatus 10 according to the third embodiment has the same apparatus configuration as the substrate processing apparatuses 10 according to the first and second embodiments. FIG. 8 is a flowchart showing an example of substrate transfer processing according to the third embodiment that is executed by the controller 15. The processing shown in FIG. 8 according to the third embodiment is executed when the wafer W is transferred from the transport robot 23 to the linear transporters 24a and 24b (hereinafter, the first linear transporter 24a as a representative) in order to transport the wafer W prior to polishing to the polishing device 21a or the like. Note that in the example shown in FIG. 8, the sensors 811 to 813 of the linear transporter 24a correspond to an example of the “first sensor” and the sensor 235 of the transport robot 23 corresponds to an example of the “second sensor”.

When the wafer W is transferred from the transport robot 23 to the first linear transporter 24a (step S102A), the sensors 811 to 813 detect whether or not the wafer W is properly positioned in the first linear transporter 24a (step S104). The processing of step S104 can be the same as the processing of step S104 in FIG. 6 described above. When the sensors 811 to 813 detect that the wafer W is properly positioned in the first linear transporter 24a (S104: Yes), the controller 15 subsequently performs normal processing with respect to the wafer W (step S120A). Normal processing is processing along normal operations performed by the substrate processing apparatus 10 described above and the wafer W is transported to the polishing device 21a or the like and polished.

On the other hand, when the sensors 811 to 813 do not detect that the wafer W is properly positioned in the first linear transporter 24a (S104: No), the controller 15 determines that there is a possibility that the wafer W has not been properly transferred. At this point, the controller 15 stops the processing with respect to the wafer W in question and notifies an error (step S106), and asks for an external input of a return operation (step S110). When the external input of a return operation is performed (S110: Yes), the controller 15 causes the wafer W to be returned from the first linear transporter 24a to the transport robot 23 (step S112A). Subsequently, the sensor 235 of the transport robot 23 detects and notifies whether or not the returned wafer W is properly positioned in the transport robot 23 (step S114A).

Next, the controller 15 asks for an external input of continuing processing (step S116). The user can perform the external input of continuing processing by confirming that the returned wafer W is properly positioned in the processing of step S114A. When the external input of continuing processing is performed by the user (S116: Yes), the controller 15 continues processing of the wafer W using the first linear transporter 24a (step S122A). In this case, the wafer W is transferred from the transport robot 23 to the first linear transporter 24a once again, and holding and transport of the wafer W by the first linear transporter 24a are allowed regardless of the detection by the sensors 811 to 813.

On the other hand, when the external input of a return operation is not performed by the user (S110: No) and when the external input of continuing processing is not performed by the user (S116: No), the controller 15 executes predetermined transport error processing (step S124).

According to the substrate transfer processing described above, control by the controller 15 when the wafer W is transferred from the transport robot 23 (an example of the second holding mechanism) to the first linear transporter 24a (an example of the first holding mechanism) is disclosed. Even in this case, the control enables even cases where a malfunction has occurred in the sensors 811 to 813 to be suitably accommodated in a similar manner to the first embodiment.

### Seventh Modification

In the first to third embodiments, an operation when the wafer W is transferred to the first linear transporter 24a has been described. However, when the wafer W is transferred to another mechanism that holds or transports the wafer W in place of or in addition to the linear transporters 24a and 24b, the controller 15 may perform processing such as that shown in FIGS. 6 to 8. In addition, when the wafer W is transferred from another mechanism that holds or transports the wafer W in place of or in addition to the top ring 25a or the transport robot 23, the controller 15 may perform processing such as that shown in FIGS. 6 to 8. In other words, if the wafer W is not detected to be properly positioned in the first holding mechanism when the wafer W is transferred from the second holding mechanism to the first holding mechanism, the controller 15 may accept a predetermined external input. Alternatively, if the wafer W is not detected to be properly positioned in the first holding mechanism when the wafer W is transferred from the second holding mechanism to the first holding mechanism, the controller 15 may return the wafer W from the first holding mechanism to the second holding mechanism. Here, each of the first holding mechanism and the second holding mechanism can be one of the transport robot 23, the transport module 14, the linear transporters 24a and 24b, the top ring 25a, the wafer station 33a, and the stage 32a.

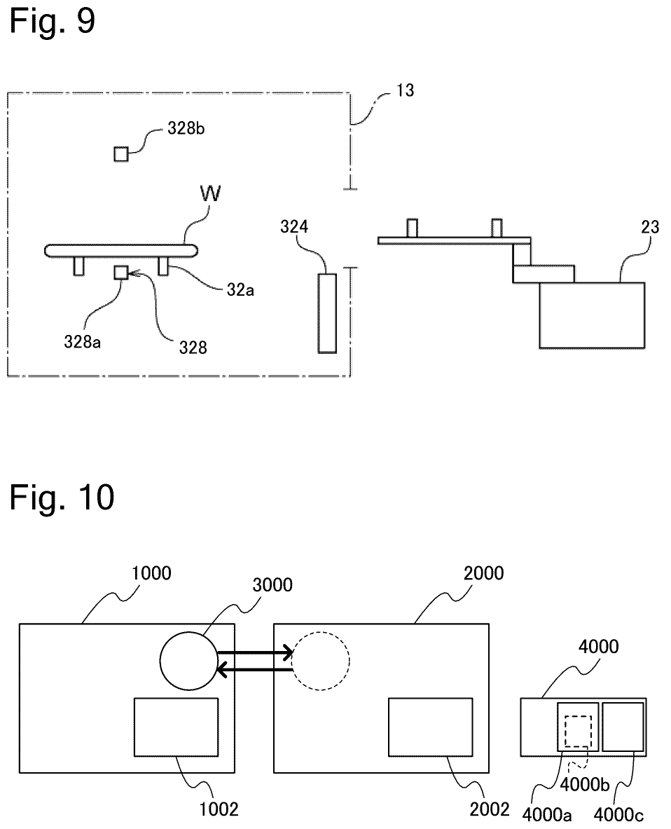

As an example, an example where the stage 32a in the cleaning module 13 corresponds to the first holding mechanism and the transport robot 23 corresponds to the second holding mechanism will be described. FIG. 9 is a diagram schematically showing an example of a transfer of a wafer between the transport robot 23 and a transport unit 32. Note that illustration of a cleaning mechanism for cleaning the wafer W in the cleaning module 13 is omitted in FIG. 9. In the example shown in FIG. 9, the cleaning module 13 is equipped with the stage 32a having a chuck for holding the wafer W and a sensor 328 for detecting that the wafer W is positioned on the stage 32a. In addition, the cleaning module 13 is provided with a shutter 324 that opens when the wafer W is transported. Note that the stage 32a may be referred to as a “substrate holder”, a “substrate chuck”, or the like.

When the shutter 324 is opened and the wafer W is transferred from the transport robot 23 to the stage 32a, the controller 15 determines whether or not the wafer W is properly positioned on the stage 32a based on detection by the sensor 328. As an example, the sensor 328 can be an optical sensor having a light projector 328a and a light receiver 328b. The sensor 328 corresponds to an example of the “first sensor”. However, whether or not the wafer W is properly positioned on the stage 32a may be determined based on detected signals of various other sensors (not illustrated) in place of or in addition to the sensor 328. In addition, the chuck included in the stage 32a may be provided with a mechanism for determining that the wafer W is properly positioned. When the wafer W is not detected to be properly positioned on the stage 32a, the controller 15 accepts a predetermined external input. Subsequently, based on the predetermined external input, the controller 15 allows processing of the wafer W using the stage 32a regardless of the detection by the sensor 328. Accordingly, the cleaning processing in the cleaning module 13 is continued with respect to the wafer W held on the stage 32a regardless of the detection by the sensor 328. Note that a return operation from the stage 32a to the transport robot 23 may be performed in a similar manner to the description given in the second embodiment.

### Fourth Embodiment

FIG. 10 is a schematic view showing a schematic configuration of a transport device according to a fourth embodiment. The transport device according to the fourth embodiment is configured to transport various objects 3000 such as a substrate, a manufactured article, a bagged article, and a cardboard box. As shown in FIG. 10, the transport device is equipped with a first holding mechanism 1000 and a second holding mechanism 2000 for holding or transporting the object 3000. The first holding mechanism 1000 and the second holding mechanism 2000 are configured so as to be capable of transferring the object 3000 to each other. The first holding mechanism 1000 and the second holding mechanism 2000 can each be any known configuration capable of holding or transporting the object 3000, including a transport belt such as a belt conveyor, a moving mechanism capable of moving the object 3000 horizontally or vertically, a transport robot such as a robot hand, and a stage for performing predetermined processing on the object 3000. Furthermore, although not limited thereto, in the transport device, the first holding mechanism 1000 may be a holding mechanism on a downstream side of the second holding mechanism 2000.

In addition, the transport device is equipped with a first sensor 1002 for detecting that the object 3000 is properly positioned in the first holding mechanism 1000 and a second sensor 2002 for detecting that the object 3000 is properly positioned in the second holding mechanism 2000. The first sensor 1002 and the second sensor 2002 need only be each capable of detecting that the object 3000 is properly positioned, and various sensors such as weight sensors, distance sensors (laser sensor, infrared sensor, X-ray sensor, and the like), image sensors, ultrasonic sensors, and contact sensors (such as a mechanical sensor) can be adopted.

Furthermore, the transport device is equipped with a controller 4000 for controlling the entire transport device. The controller 4000 may be configured as a microcomputer equipped with a CPU, a memory 4000a, a display apparatus 4000c, and the like and capable of performing predetermined functions using software or may be configured as a hardware circuit for performing dedicated arithmetic processing. The memory 4000a is an example of a storage medium and stores a program 4000b for realizing the method according to one embodiment of the present invention. The display apparatus 4000c is an apparatus for displaying information to the user in a similar manner to the display apparatus 15c according to the first embodiment. The controller 4000 can transmit control commands to the first holding mechanism 1000 and the second holding mechanism 2000. In addition, detected signals by the first sensor 1002 and the second sensor 2002 are input to the controller 4000.

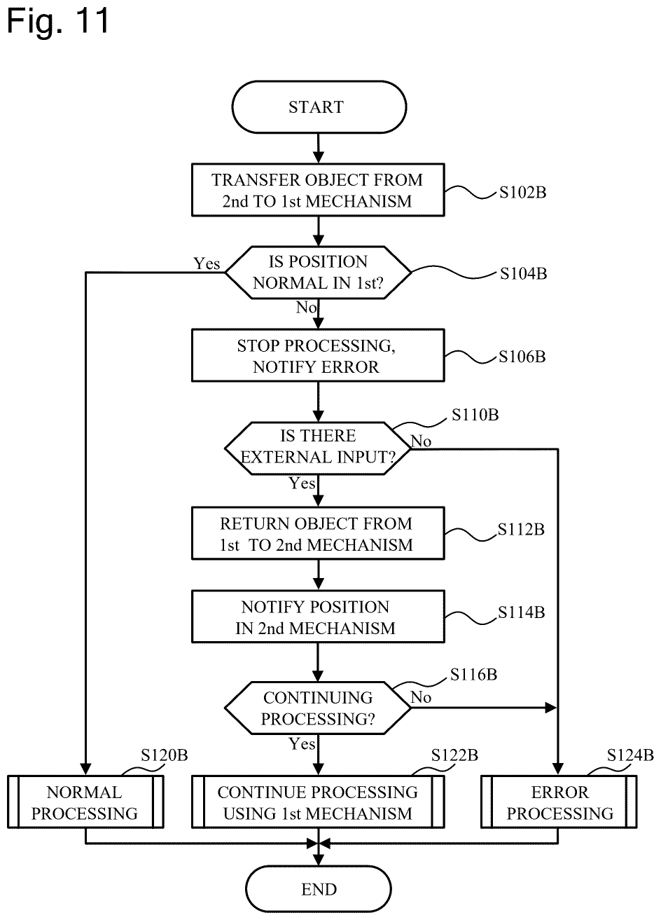

FIG. 11 is a flowchart showing an example of object transfer processing according to the fourth embodiment that is executed by the controller 4000. First, the controller 4000 controls the second and first holding mechanisms 2000 and 1000 so that the object 3000 is transferred from the second holding mechanism 2000 to the first holding mechanism 1000 (step S102B). When the object 3000 is transferred from the second holding mechanism 2000 to the first holding mechanism 1000, the first sensor 1002 detects whether or not the object 3000 is properly positioned in the first holding mechanism 1000 (step S104B). When the first sensor 1002 detects that the object 3000 is properly positioned in the first holding mechanism 1000 (S104B: Yes), the controller 4000 subsequently performs normal processing (step S120B). In the normal processing, processing such as holding or transport of the object 3000 using the first holding mechanism 1000 is continued. Accordingly, the object 3000 transferred from the second holding mechanism 2000 to the first holding mechanism 1000 is subsequently subjected to predetermined processing while being held or transported by the first holding mechanism 1000 or transported to another location.

On the other hand, when the first sensor 1002 does not detect that the object 3000 is properly positioned in the first holding mechanism 1000 (S104B: No), the controller 4000 determines that there is a possibility that the object 3000 has not been properly transferred. At this point, the controller 4000 stops the processing with respect to the object 3000 in question and notifies an error (step S106B), and asks for an external input of a return operation (step S110B). Here, the external input of a return operation corresponds to an example of the predetermined external input. The predetermined external input is an input used by the user to allow processing to be performed regardless of the detection by the first sensor 1002 when the object 3000 is not properly detected by the first sensor 1002. The predetermined external input may be performed by having the user operate an inputter (not illustrated) provided in the transport device or performed from the outside through wired or wireless communication. In addition, as an example, the predetermined external input may be configured so that the input can be performed in conjunction with the notification of an error. Furthermore, the controller 4000 may notify the user by using the display apparatus 4000c or the like to perform the predetermined external input together with the notification of an error and ask the user for the predetermined external input.

When the external input of a return operation is performed (S110B: Yes), the controller 4000 causes the object 3000 to be returned from the first holding mechanism 1000 to the second holding mechanism 2000 (step S112B). Subsequently, the second sensor 2002 of the second holding mechanism 2000 detects and notifies whether or not the returned object 3000 is properly positioned in the second holding mechanism 2000 (step S114B).

Next, the controller 4000 asks for an external input of continuing processing (step S116B). The user can perform the external input of continuing processing by confirming that the returned object 3000 is properly positioned in the processing of step S114B. When the external input of continuing processing is performed by the user (S116B: Yes), the controller 4000 continues processing using the first holding mechanism 1000 (step S122B). In this case, the object 3000 is transferred from the second holding mechanism 2000 to the first holding mechanism 1000 once again, and holding or transport of the object 3000 by the first holding mechanism 1000 is allowed regardless of the detection by the first sensor 1002.

On the other hand, when the external input of a return operation is not performed by the user (S110B: No) and when the external input of continuing processing is not performed by the user (S116B: No), the controller 4000 executes predetermined transport error processing (step S124B). In the transport error processing, the controller 4000 may prohibit holding and transport of the object 3000 by the first holding mechanism 1000. In addition, in the transport error processing, the controller 4000 may notify that there is a possibility that an error has occurred in the object 3000 using the display apparatus 4000c, a lamp (not illustrated), a buzzer, or the like.

According to the transport device described above, control by the controller 4000 when the object 3000 is transferred from the second holding mechanism 2000 to the first holding mechanism 1000 is disclosed. In other words, when the first sensor 1002 does not detect that the object 3000 is properly positioned, the controller 4000 accepts a predetermined external input. The controller 4000 causes the object 3000 to be returned from the first holding mechanism 1000 to the second holding mechanism 2000 based on the predetermined external input being performed. In addition, when the returned object 3000 is properly positioned in the second holding mechanism 2000, the controller 4000 allows holding and transport of the object 3000 by the first holding mechanism 1000 regardless of the detection by the first sensor 1002. Such control enables even cases where a malfunction has occurred in the first sensor 1002 to be suitably accommodated.

### Eighth Modification

In the fourth embodiment, when the first sensor 1002 does not detect that the object 3000 is properly positioned, a return operation of the object 3000 is to be executed in a similar manner to the second embodiment. Alternatively, when the first sensor 1002 does not detect that the object 3000 is properly positioned, the transport device may accept a predetermined external input and allow processing of the object 3000 using the first holding mechanism 1000 based on the predetermined external input regardless of the detection by the first sensor 1002 in a similar manner to the first embodiment. In addition, the first to sixth modifications described above can be combined with the third and fourth embodiments. As an example, the first sensor 1002 may have a plurality of sensors and the controller 4000 may execute control as described in the third and fourth modifications based on detection by the plurality of sensors.

The present invention can also be described as the following modes.

[Mode 1] Mode 1 proposes a substrate processing apparatus, including: a first holding mechanism for holding a substrate; a second holding mechanism for holding a substrate, the second holding mechanism being configured to be capable of transferring a substrate to and from the first holding mechanism; a first sensor for detecting that a substrate is properly positioned in the first holding mechanism; and a controller configured to accept a predetermined external input if the first sensor does not detect that a substrate is properly positioned in the first holding mechanism when the substrate is transferred from the second holding mechanism to the first holding mechanism and to allow the substrate to be processed or transported using the first holding mechanism based on the predetermined external input being performed regardless of the detection by the first sensor.

According to mode 1, processing can be properly implemented even when a malfunction occurs in the first sensor for detecting that a substrate is properly positioned.

[Mode 2] According to mode 2, in mode 1, the substrate processing apparatus includes a second sensor for detecting that a substrate is properly positioned in the second holding mechanism, wherein the controller is configured to allow the substrate to be processed or transported using the first holding mechanism regardless of detection by the first sensor based on the predetermined external input being performed, the substrate being returned from the first holding mechanism to the second holding mechanism, and the second sensor detecting that the returned substrate is properly positioned in the second holding mechanism.

According to mode 2, processing can be properly implemented based on the second sensor even when a malfunction occurs in the first sensor.

[Mode 3] According to mode 3, in mode 1 or 2, one of the first holding mechanism and the second holding mechanism is a top ring for holding a substrate and pressing the substrate against a polishing surface, and the other of the first holding mechanism and the second holding mechanism is a transport mechanism for transporting the substrate.

[Mode 4] According to mode 4, in mode 1 or 2, one of the first holding mechanism and the second holding mechanism is a stage on which a substrate is placed, and the other of the first holding mechanism and the second holding mechanism is a transport mechanism for transferring the substrate to and from the stage.

[Mode 5] According to mode 5, in modes 1 to 4, the controller is configured, when allowing the substrate to be processed or transported using the first holding mechanism regardless of detection by the first sensor, to disable the detection by the first sensor until a predetermined period of time elapses and to enable the detection by the first sensor after the predetermined period of time elapses.

According to mode 5, when a malfunction is occurring in the first sensor, the malfunction of the first sensor can be prevented from being overlooked for a long period of time while preventing processing from being repeatedly stopped.

[Mode 6] Mode 6 proposes a substrate processing method in a substrate processing apparatus including: a first holding mechanism for holding a substrate; a second holding mechanism for holding a substrate, the second holding mechanism being configured to be capable of transferring a substrate to and from the first holding mechanism; and a first sensor for detecting that a substrate is properly positioned in the first holding mechanism, the substrate processing method including: detecting whether or not a substrate is properly positioned in the first holding mechanism with the first sensor when the substrate is transferred from the second holding mechanism to the first holding mechanism; accepting a predetermined external input to the substrate processing apparatus when the substrate is not detected to be properly positioned in the first holding mechanism; and allowing the substrate to be processed or transported using the first holding mechanism based on the predetermined external input being performed regardless of the detection by the first sensor.

According to mode 6, processing can be properly implemented even when a malfunction occurs in the first sensor for detecting that a substrate is properly positioned.

[Mode 7] Mode 7 proposes a program that causes a computer to execute a substrate processing method in a substrate processing apparatus, the method including: detecting whether or not a substrate is properly positioned in a first holding mechanism with a first sensor when the substrate is transferred from a second holding mechanism to the first holding mechanism; accepting a predetermined external input to the substrate processing apparatus when the substrate is not detected to be properly positioned in the first holding mechanism; and allowing the substrate to be processed or transported using the first holding mechanism based on the predetermined external input being performed regardless of the detection by the first sensor.

According to mode 7, processing can be properly implemented even when a malfunction occurs in the first sensor for detecting that a substrate is properly positioned.

[Mode 8] Mode 8 proposes a computer-readable storage medium storing the program described in mode 7.

[Mode 9] Mode 9 proposes a transport device, including: a first holding mechanism for holding an object; a second holding mechanism for holding an object, the second holding mechanism being configured to be capable of transferring an object to and from the first holding mechanism; a first sensor for detecting that an object is properly positioned in the first holding mechanism; and a controller configured to accept a predetermined external input if the first sensor does not detect that an object is properly positioned in the first holding mechanism when the object is transferred from the second holding mechanism to the first holding mechanism and to allow the object to be processed or transported using the first holding mechanism based on the predetermined external input being performed regardless of the detection by the first sensor.

According to mode 9, processing can be properly implemented even when a malfunction occurs in the first sensor for detecting that an object is properly positioned.

[Mode 10] Mode 10 proposes a transport method in a transport device including: a first holding mechanism for holding an object; a second holding mechanism for holding an object, the second holding mechanism being configured to be capable of transferring an object to and from the first holding mechanism; and a first sensor for detecting that an object is properly positioned in the first holding mechanism, the transport method including: detecting whether or not an object is properly positioned in the first holding mechanism with the first sensor when the object is transferred from the second holding mechanism to the first holding mechanism; accepting a predetermined external input to the transport device when the object is not detected to be properly positioned in the first holding mechanism; and allowing the object to be processed or transported using the first holding mechanism based on the predetermined external input being performed regardless of the detection by the first sensor.

According to mode 10, processing can be properly implemented even when a malfunction occurs in the first sensor for detecting that an object is properly positioned.

[Mode 11] Mode 11 proposes a program that causes a computer to execute a transport method in a transport device, the method including: detecting whether or not an object is properly positioned in a first holding mechanism with a first sensor when the object is transferred from a second holding mechanism to the first holding mechanism; accepting a predetermined external input to the transport device when the object is not detected to be properly positioned in the first holding mechanism; and allowing the object to be processed or transported using the first holding mechanism based on the predetermined external input being performed regardless of the detection by the first sensor.

According to mode 11, processing can be properly implemented even when a malfunction occurs in the first sensor for detecting that an object is properly positioned.

[Mode 12] Mode 12 proposes a computer-readable storage medium storing the program described in mode 11.

While embodiments of the present invention have been described above, it should be noted that the embodiments of the invention described above are for facilitating understanding of the present invention and is not intended to limit the present invention. The present invention can be modified or improved without departing from the spirit and scope thereof and the present invention is obviously intended to cover all equivalents thereof. In addition, any combination of embodiments and modifications is possible within the scope of solving at least a part of the problems described above or achieving at least some of the effects described above, and any combination or omission of the components described in the claims and the specification is possible.

What is claimed is:

1. A substrate processing apparatus, comprising:
a first holding mechanism for holding a substrate;
a second holding mechanism for holding a substrate, the second holding mechanism being configured to be capable of transferring a substrate to and from the first holding mechanism;
a first sensor for detecting that a substrate is properly positioned in the first holding mechanism; and
a controller configured to accept a predetermined external input if the first sensor does not detect that a substrate is properly positioned in the first holding mechanism when the substrate is transferred from the second holding mechanism to the first holding mechanism and to allow the substrate to be processed or transported using the first holding mechanism based on the predetermined external input being performed regardless of the detection by the first sensor.

2. The substrate processing apparatus according to claim 1, comprising:
a second sensor for detecting that a substrate is properly positioned in the second holding mechanism, wherein
the controller is configured to allow the substrate to be processed or transported using the first holding mechanism regardless of detection by the first sensor based on the predetermined external input being performed, the substrate being returned from the first holding mechanism to the second holding mechanism, and the second sensor detecting that the returned substrate is properly positioned in the second holding mechanism.

3. The substrate processing apparatus according to claim 1, wherein
one of the first holding mechanism and the second holding mechanism is a top ring for holding a substrate and pressing the substrate against a polishing surface, and
the other of the first holding mechanism and the second holding mechanism is a transport mechanism for transporting the substrate.

4. The substrate processing apparatus according to claim 1, wherein
one of the first holding mechanism and the second holding mechanism is a stage on which a substrate is placed, and
the other of the first holding mechanism and the second holding mechanism is a transport mechanism for transferring the substrate to and from the stage.

5. The substrate processing apparatus according to claim 1, wherein the controller is configured, when allowing the substrate to be processed or transported using the first holding mechanism regardless of detection by the first sensor, to disable the detection by the first sensor until a predetermined period of time elapses and to enable the detection by the first sensor after the predetermined period of time elapses.

6. A substrate processing method in a substrate processing apparatus including: a first holding mechanism for holding a substrate; a second holding mechanism for holding a substrate, the second holding mechanism being configured to be capable of transferring a substrate to and from the first holding mechanism; and a first sensor for detecting that a substrate is properly positioned in the first holding mechanism, the substrate processing method comprising:
detecting whether or not a substrate is properly positioned in the first holding mechanism with the first sensor when the substrate is transferred from the second holding mechanism to the first holding mechanism;
accepting a predetermined external input to the substrate processing apparatus when the substrate is not detected to be properly positioned in the first holding mechanism; and
allowing the substrate to be processed or transported using the first holding mechanism based on the predetermined external input being performed regardless of the detection by the first sensor.

7. A computer-readable storage medium storing a program for causing a computer to execute a substrate processing method in a substrate processing apparatus, the method comprising:
detecting whether or not a substrate is properly positioned in a first holding mechanism with a first sensor when the substrate is transferred from a second holding mechanism to the first holding mechanism;
accepting a predetermined external input to the substrate processing apparatus when the substrate is not detected to be properly positioned in the first holding mechanism; and
allowing the substrate to be processed or transported using the first holding mechanism based on the predetermined external input being performed regardless of the detection by the first sensor.

8. A transport device, comprising:
a first holding mechanism for holding an object;
a second holding mechanism for holding an object, the second holding mechanism being configured to be capable of transferring an object to and from the first holding mechanism;
a first sensor for detecting that an object is properly positioned in the first holding mechanism; and
a controller configured to accept a predetermined external input if the first sensor does not detect that an object is properly positioned in the first holding mechanism when the object is transferred from the second holding mechanism to the first holding mechanism and to allow the object to be processed or transported using the first holding mechanism based on the predetermined external input being performed regardless of the detection by the first sensor.

9. A transport method in a transport device including: a first holding mechanism for holding an object; a second holding mechanism for holding an object, the second holding mechanism being configured to be capable of transferring an object to and from the first holding mechanism; and a first sensor for detecting that an object is properly positioned in the first holding mechanism, the transport method comprising:
detecting whether or not an object is properly positioned in the first holding mechanism with the first sensor when the object is transferred from the second holding mechanism to the first holding mechanism;
accepting a predetermined external input to the transport device when the object is not detected to be properly positioned in the first holding mechanism; and
allowing the object to be processed or transported using the first holding mechanism based on the predetermined external input being performed regardless of the detection by the first sensor.

10. A computer-readable storage medium storing a program for causing a computer to execute a transport method in a transport device, the method comprising:
detecting whether or not an object is properly positioned in a first holding mechanism with a first sensor when the object is transferred from a second holding mechanism to the first holding mechanism;
accepting a predetermined external input to the transport device when the object is not detected to be properly positioned in the first holding mechanism; and
allowing the object to be processed or transported using the first holding mechanism based on the predetermined external input being performed regardless of the detection by the first sensor.
